(19) United States
(12) Patent Application Publication
(10) Pub. No.: US 2013/0322009 A1
(43) Pub. Date: Dec. 5, 2013

(54) HARD DISK CAGE AND ELECTRONIC DEVICE USING THE SAME

(71) Applicant: HON HAI PRECISION INDUSTRY CO., LTD, New Taipei (TW)

(72) Inventor: SHENG-HAN LIN, New Taipei (TW)

(73) Assignee: HON HAI PRECISION INDUSTRY CO., LTD., New Taipei (TW)

(21) Appl. No.: 13/723,205

(22) Filed: Dec. 21, 2012

(30) Foreign Application Priority Data
May 29, 2012 (TW) 101119220

(51) Int. Cl. G06F 1/16; H05K 5/02

(52) U.S. Cl. CPC G06F 1/16; H05K 5/02
USPC 361/679.34; 312/223.2

(57) ABSTRACT

A hard disk cage for supporting a hard disk includes a frame, and a vibration-proof assembly attached on the peripheral wall of the frame. The vibration-proof assembly absorbs vibration induced by the hard disk and cuts off vibration transmitted by the frame. An electronic device using the hard disk cage is also described.

### BACKGROUND

1. Technical Field

The present disclosure generally relates to hard disk cages, and particularly to a hard disk cage for use in an electronic device.

2. Description of Related Art

Hard drives are widely used in electronic devices (i.e., computers) to drive hard disks. Hard disks are commonly high-capacity designed. The high-capacity hard disks have high running speed when in use. However, the higher speed the hard disk runs, the stronger rotational vibration the hard disk causes, and the high speed hard disk is much more prone to be affected by external vibrations (such as, the vibrations induced by cooling device in server). As a result, the hard disk may be performance degraded, and more seriously, results in an operating failure of the hard disk.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an exploded view of an electronic device having a hard disk cage in accordance with an exemplary embodiment.

FIG. 2 is a cross-sectional view of the electronic device shown in FIG. 1 in assembly.

FIG. 3 is an enlarged view of portion III in FIG. 2.

### DETAILED DESCRIPTION

According to an exemplary embodiment, a hard disk cage for supporting hard disks is disclosed. The hard disk cage is used in an electronic device, such as a personal computer, a server, for example.

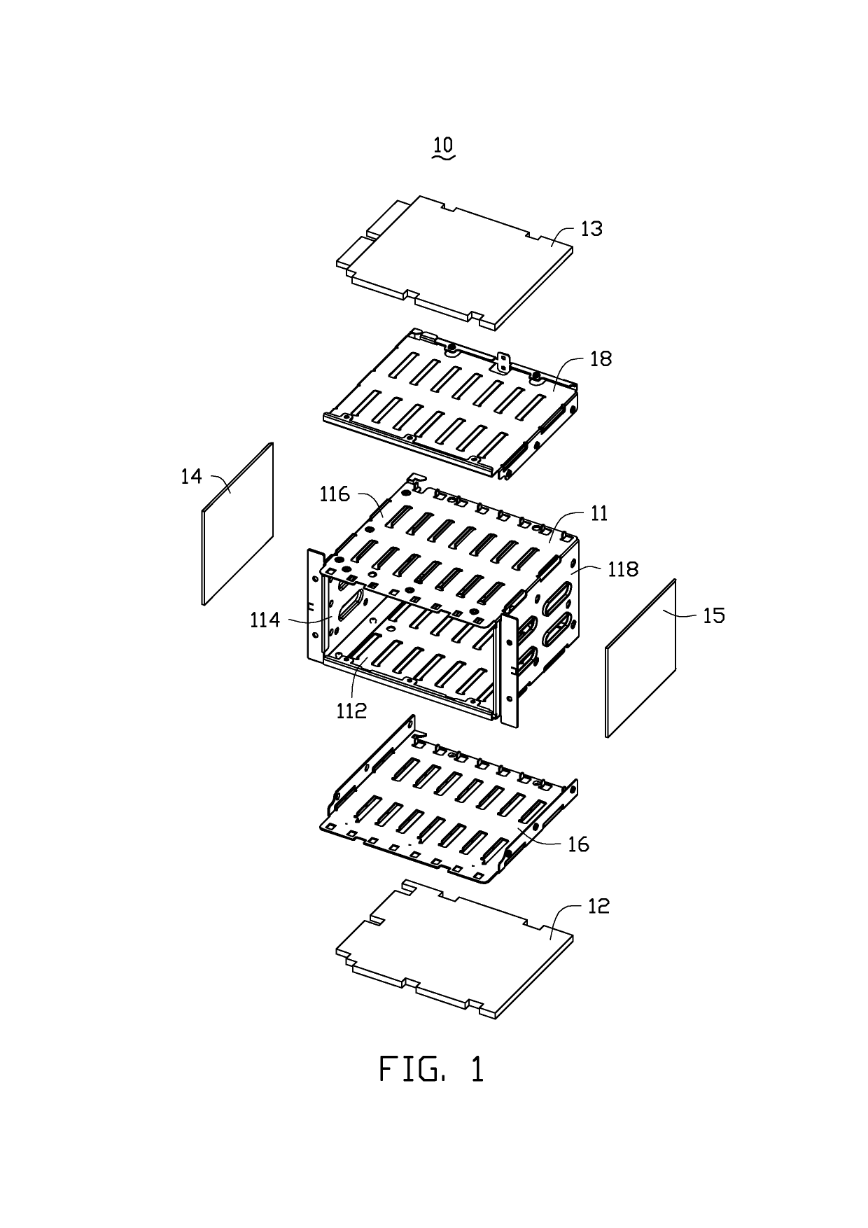

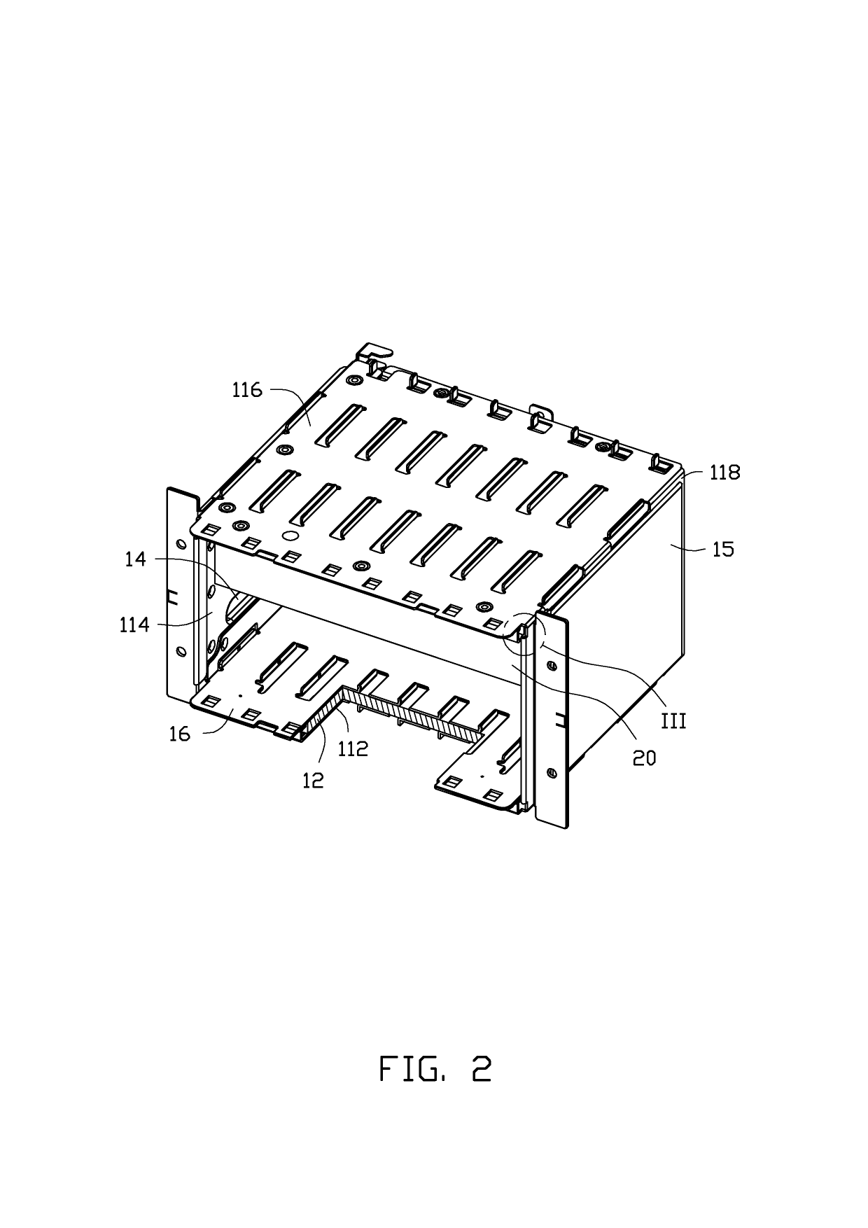

FIGS. 1 and 2 show a hard disk cage 10 which is for supporting or receiving a hard disk 20. The hard disk cage 10 includes a frame 11, a first vibration-proof block 12, a second vibration-proof block 13, a first vibration-proof plate 14, and a second vibration-proof plate 15.

The frame 11 is for receiving the hard disk 20. In the embodiment, the frame 11 includes a first holding board 112, a first side board 114, a second holding board 116, and a second side board 118 which connect together end-to-end. When the hard disk 20 is received in the frame 11, the hard disk 20 is clamped by the first side board 114, the second holding board 116, and the second side board 118 to be stably engaged in the frame 11.

The first vibration-proof block 12 is attached (such as adhered) to the first holding board 112 to absorb the external vibration (such as vibrations induced by cooling device in server) transmitted by the first vibration-proof block 12 and absorb the rotational vibration induced by the hard disk 20. In the embodiment, the first vibration-proof block 12 is attached on the surface of the first holding board 112 towards the second holding board 116. The hard disk cage 10 may further include a first fastening board 16 which covers the first vibration-proof block 12 and is secured (such as by screws) with the first holding board 112 to enhance the stability of the first vibration-proof block 12 mounting on the first holding board 112.

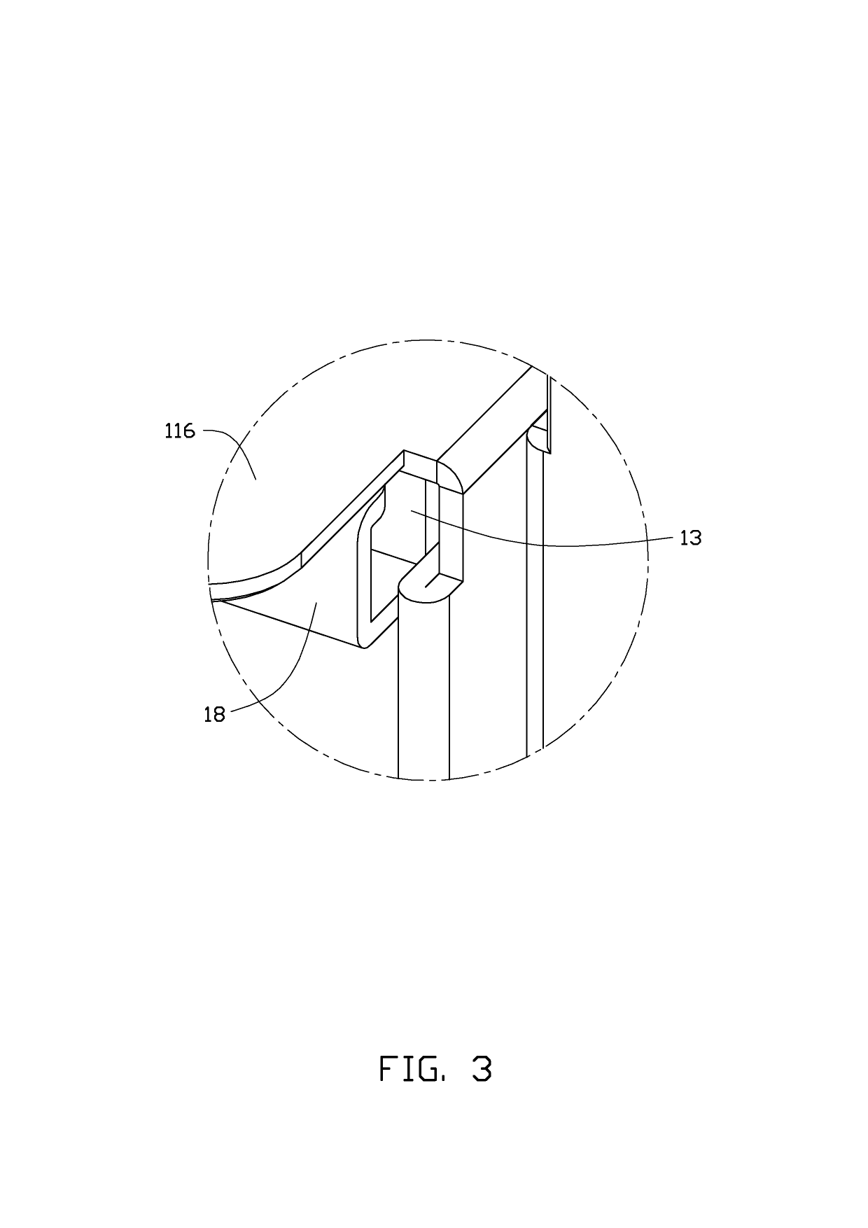

FIG. 3 also shows that the second vibration-proof block 13 is attached (such as adhered) to the second holding board 116 to absorb the external vibration transmitted by the second holding board 116 and absorb the rotational vibration induced by the hard disk 20. In the embodiment, the second vibration-proof block 13 is attached on the surface of the second holding board 116 towards the first holding board 112. The hard disk cage 10 may further include a second fastening board 18 which covers the second vibration-proof block 13 and is secured (by such things as screws) with the second holding board 116 to enhance the stability of the second vibration-proof block 13 mounting on the second holding board 116.

The first vibration-proof plate 14 is attached (such as adhered) to the first side board 114 to absorb the external vibration transmitted by the first side board 114 and absorb the rotational vibration induced by the hard disk 20. In the embodiment, the first vibration-proof plate 14 is attached on the surface of the first side board 114 away from the second side board 118.

The second vibration-proof plate 15 is attached (such as adhered) to the second side board 118 to absorb the external vibration transmitted by the second side board 118 and absorb the rotational vibration induced by the hard disk 20. In the embodiment, the second vibration-proof plate 15 is attached on the surface of the second side board 118 away from the first side board 114.

The hard disk cage 10 of the exemplary embodiment defines vibration-proof assembly, that is, the first vibration-proof block 12, the second vibration-proof block 13, the first vibration-proof plate 14, and the second vibration-proof plate 15. When the hard disk 20 runs at a high speed, the vibration-proof assembly can effectively absorb the vibration induced by the hard disk 20. Furthermore, the vibration-proof assembly can also absorb external vibrations transmitted by the frame 11 of the hard disk cage 10. As a result, the exemplary hard disk 20 runs stably and has optimal performance.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A hard disk cage for supporting a hard disk, the hard disk cage comprising:
a frame; and
a vibration-proof assembly attached on the peripheral wall of the frame, the vibration-proof assembly absorbing vibration induced by the hard disk and cutting off vibration transmitted by the frame.

2. The hard disk cage as claimed in claim 1, wherein the vibration-proof assembly comprises a first vibration-proof block and a second vibration-proof block, the frame comprises a first holding board, a first side board, a second holding board, and a second side board which connect together end-to-end, the first vibration-proof block is attached to the first holding board, and the second vibration-proof block is attached to the second holding board.

3. The hard disk cage as claimed in claim 2, wherein the vibration-proof assembly comprises a first vibration-proof plate and a second vibration-proof plate, the first vibration-proof plate is attached to the first side board, and the second vibration-proof plate is attached to the second side board.

4. The hard disk cage as claimed in claim 3, wherein when the hard disk is received in the frame, the hard disk is clamped by the first side board, the second holding board, and the second side board.

5. The hard disk cage as claimed in claim 2, wherein the first vibration-proof block is attached on the surface of the first holding board towards the second holding board.

6. The hard disk cage as claimed in claim 2, wherein the hard disk cage comprises a first fastening board, the first fastening board covers the first vibration-proof block and is secured with the first holding board.

7. The hard disk cage as claimed in claim 2, wherein the second vibration-proof block is attached on the surface of the second holding board towards the first holding board.

8. The hard disk cage as claimed in claim 2, wherein the hard disk cage comprises a second fastening board, the second fastening board covers the second vibration-proof block and is secured with the second holding board.

9. The hard disk cage as claimed in claim 3, wherein the first vibration-proof plate is attached on the surface of the first side board away from the second side board.

10. The hard disk cage as claimed in claim 3, wherein the second vibration-proof plate is attached on the surface of the second side board away from the first side board.

11. An electronic device, comprising:
a hard disk; and
a hard disk cage for supporting the hard disk, the hard disk cage comprising:
a frame; and
a vibration-proof assembly attached on the peripheral wall of the frame, the vibration-proof assembly absorbing vibration induced by the hard disk and cutting off vibration transmitted by the frame.

12. The electronic device as claimed in claim 11, wherein the vibration-proof assembly comprises a first vibration-proof block and a second vibration-proof block, the frame comprises a first holding board, a first side board, a second holding board, and a second side board which connect together end-to-end, the first vibration-proof block is attached to the first holding board, and the second vibration-proof block is attached to the second holding board.

13. The electronic device as claimed in claim 12, wherein the vibration-proof assembly comprises a first vibration-proof plate and a second vibration-proof plate, the first vibration-proof plate is attached to the first side board, and the second vibration-proof plate is attached to the second side board.

14. The electronic device as claimed in claim 13, wherein when the hard disk is received in the frame, the hard disk is clamped by the first side board, the second holding board, and the second side board.

15. The electronic device as claimed in claim 12, wherein the first vibration-proof block is attached on the surface of the first holding board towards the second holding board.

16. The electronic device as claimed in claim 12, wherein the hard disk cage comprises a first fastening board, the first fastening board covers the first vibration-proof block and is secured with the first holding board.

17. The electronic device as claimed in claim 12, wherein the second vibration-proof block is attached on the surface of the second holding board towards the first holding board.

18. The electronic device as claimed in claim 12, wherein the hard disk cage comprises a second fastening board, the second fastening board covers the second vibration-proof block and is secured with the second holding board.

19. The electronic device as claimed in claim 13, wherein the first vibration-proof plate is attached on the surface of the first side board away from the second side board.

20. The electronic device as claimed in claim 13, wherein the second vibration-proof plate is attached on the surface of the second side board away from the first side board.
